(19) United States
(12) Patent Application Publication
(10) Pub. No.: US 2018/0236312 A1
(43) Pub. Date: Aug. 23, 2018

(54) DEVICE USED TO ASSEMBLE A CIRCUIT MODULE AND A BATTERY IN A BALL AND A MANUFACTURING METHOD THEREOF

(71) Applicant: GENGEE TECHNOLOGY CO., LTD., Xiamen, Fujian (CN)

(72) Inventor: Daisung KUO, Xiamen, Fujian (CN)

(73) Assignee: GENGEE TECHNOLOGY CO., LTD., Xiamen, Fujian (CN)

(21) Appl. No.: 15/754,883

(22) PCT Filed: Mar. 17, 2016
(86) PCT No.: PCT/CN2016/076603

§ 371 Date: Feb. 23, 2018

(30) Foreign Application Priority Data
Sep. 2, 2015 (CN) 201510555887.5

(51) Int. Cl. A63B 45/00; H05K 5/03; H05K 5/00; H02J 7/02; A63B 43/00

(52) U.S. Cl. CPC A63B 45/00; H05K 5/03; H05K 5/0086; H02J 7/025; B29D 22/04; A63B 2243/0025; A63B 2243/0037; A63B 2220/833; A63B 43/004

(57) ABSTRACT

A device used to assemble a circuit module and a battery in a ball includes a battery that is not fixedly connected. The manufacturing method includes that the interior of the ball body is formed by high temperature vulcanization and wrapped by an external layer, then the battery is pushed through the normal-close elastic assembly hole of the elastic cover to the battery assembly position.

### FIELD OF THE INVENTION

The present invention relates to a component and an application used to assemble electric module in a ball, particularly to a device used to assemble a circuit module and a battery in a ball and a manufacturing method thereof.

### BACKGROUND OF THE INVENTION

With the development of intelligentization in varies fields, sports instruments enter the era of the all-round intelligentization. Therein, for a ball, like a basketball or football, built-in sensors and necessary circuit modules are disposed in the ball to collect sports data. The ball interior is formed by vulcanization in high temperature, but high temperature damages battery even results in explosion. Therefore, in existing technology of manufacturing a ball with built-in circuit and battery, the interior is firstly vulcanized and then the battery is put into a fixing position of the ball, and is wrapped by a leather layer to form the ball body. Said manufacturing method makes the ball body with weak elasticity in the fixing position, the normal usage of the ball is influenced.

### SUMMARY OF THE INVENTION

The object of the present invention is to provided with a device used to assemble a circuit module and a battery in a ball and the manufacturing method thereof that the ball elasticity doesn't influenced to overcome the disadvantages of the existing known technology.

The technical proposal of the present invention is that:

A device used to assemble a circuit module and battery in a ball, wherein comprising an inner housing, an assembly chamber and a connecting portion; the circuit module is fixedly assembled in the inner housing, the inner housing is disposed in the assembly housing, the top surface of the assembly housing extends outwardly to form the connecting portion, the opening of the top surface of the assembly chamber is disposed with an elastic cover; the inner housing is disposed with a battery assembly position, the elastic cover is disposed with a normal-close elastic assembly hole at the position according to the battery assembly position; the battery is pushed to the battery assembly position through the normal-close elastic assembly hole to provide power to the circuit module.

In another preferred embodiment, the battery assembly position is disposed with a conductive sheet corresponding to the electrode of the battery, the electrode of the battery contacts with the conductive sheet after the battery, which is used to supply power to the circuit module, is assembled to the battery assembly position.

In another preferred embodiment, the conductive sheet is an elastic metal sheet connected to the circuit module.

In another preferred embodiment, the conductive sheet is an arc surface extending towards the batter assembly position, the convex side of the arc surface is faced to the battery.

In another preferred embodiment, the elastic cover comprises two plug covers abutting against each other to close the opening of the assembly chamber, the position the two plug covers abutting against each other is disposed with the normal-close elastic assembly hole.

In another preferred embodiment, the internal side surface of the inner housing of the battery assembly position is disposed with a guide groove, the battery is pushed along the guide groove.

In another preferred embodiment, the inner housing is disposed with a limit groove, the circuit module is limited in the limit groove.

In another preferred embodiment, the battery is a rechargeable battery; the circuit module comprises a wireless charging circuit, a receiving coil of which is disposed at the top surface of the connecting portion or is embedded in a sinking hole of the connecting portion.

In another preferred embodiment, the connecting portion is a sheet shaped connecting surface horizontally extending outwardly from the top surface of the assembly chamber.

A manufacturing method of a ball disposed with the device, comprising the steps:
1) assembling the circuit module in the inner housing, assembling the inner housing in the assembly chamber;
2) vulcanizing the connecting portion and the ball interior to an integration structure and wrapping the same;
3) putting the elastic cover at the top end opening of the assembly chamber, pushing the battery through the normal-close elastic assembly hole of the elastic cover to the battery assembly position.

A manufacturing method of a ball disposed with the device, comprising the steps:
1) assembling the circuit module in the inner housing, assembling the inner housing in the assembly chamber;
2) adhering the connecting portion and the ball interior to an integration structure and wrapping the same, the connecting portion is disposed between the interior and the external wrapping layer;
3) putting the elastic cover at the top end opening of the assembly chamber, pushing the battery through the normal-close elastic assembly hole of the elastic cover to the battery assembly position.

The present invention has advantages as follows:

The device used to assemble a circuit module and a battery in a ball of the present invention is provided that the battery is not fixedly connected, the interior of the ball body is formed by high temperature vulcanization and wrapped by an external layer, then the batter is pushed through the normal-close elastic assembly hole of the elastic cover to the battery assembly position. The present invention avoids high temperature damaging the battery during the manufacturing. The elastic cover makes the ball body without weak elasticity problem at the position of the ball disposing the assembly chamber.

In the present invention, the conductive sheet can be applied with elastic metal sheet, which makes the conductive sheet contacted tightly with the electrode of the battery; during long time service, the conductive sheet would not deform due to slight vibration, it is recoverable, it would not lead to bad contact.

Based on above mentioned device, the manufacturing method of the present invention changes the traditional manufacturing processes, the present invention needn't to consider that the high temperature would damage the battery, so it needs to change the manufacturing parameter, the ball performance would be influenced, the traditional manufacturing method needs to disposed anti-damage process, which reduces the manufacturing efficiency and increases the manufacturing cost.

### BRIEF DESCRIPTION OF THE DRAWINGS

FIG. 1 illustrates a sectional diagram of the device of the present invention disposed in a ball.

FIG. 2 illustrates a sectional diagram of the device.

FIG. 3 illustrates a schematic diagram of the wireless coil disposed at the top surface of the connecting portion.

FIG. 4 illustrates a schematic diagram of the wireless coil embedded in a sinking hole of the connecting portion.

Reference signs: connecting portion 10, assembly chamber 11, inner housing 12, circuit module 13, conductive sheet 14, battery 15, battery assembly position 16, elastic cover 17, normal-close elastic assembly hole 18, guide groove 19, receiving coil 20, sinking hole 21.

### DETAILED DESCRIPTION OF THE EMBODIMENTS

The present invention will be further described with the drawings and the embodiments.

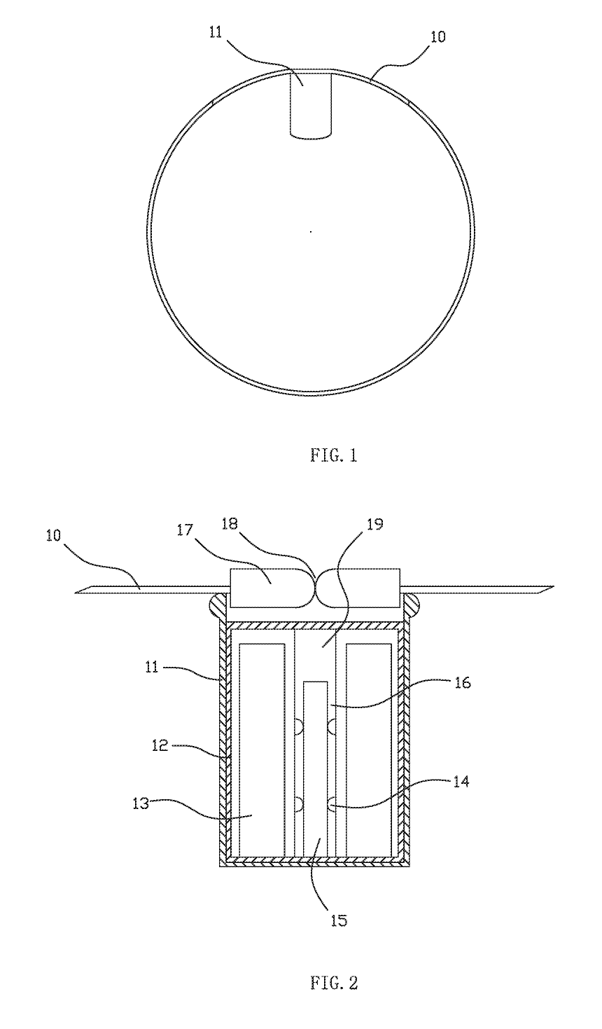

Considering that the battery 15 would be damaged and the position of the battery 15 would be weak in elasticity during high temperature vulcanization of the ball body manufactured by traditional method, the present invention is provided with a device used to assemble a circuit module 13 and a battery 15 in a ball that the elasticity of the ball is normal, as figured in FIG. 1 and FIG. 2, the device comprises an inner housing 12, an assembly chamber 11, a connecting portion 10, the circuit module 13 is fixedly assembled in the inner housing 12; to prevent the circuit module 13 shaking or moving in the inner housing 12, resulting in damage or data collection error, the inner housing 12 is disposed with a limit groove, and the circuit module 13 is limited and assembled in the limit groove. The circuit module 13 is tightly coupled to the limit groove, ensuring the stability of the circuit module 13 in the inner housing 12. the inner housing 12 is disposed in the assembly chamber 11, the top surface 11 of the assembly chamber extends outwardly to form the connecting portion 10; for the convenience of later process, the connecting portion 10 is a sheet shaped connecting surface extending horizontally outwardly from the top surface of the assembly chamber 11. The sheet shaped surface and the ball interior can be conveniently vulcanized to form an integrate structure; the sheet shaped surface is also convenient adhered to the ball interior and an outer leather layer. To overcome the gap of the interior (the position disposing the assembly chamber 11), which resulting in weak elasticity of this position, the present invention is provided that the opening of the top surface of the assembly chamber 11 is disposed with an elastic cover 17, the inner housing 12 is disposed with a battery assembly position 16, the elastic cover comprises two plug covers, which are abutting against each other to close the opening of the assembly chamber, the elastic cover 17 is disposed with a normal-close elastic assembly hole 18 at the position corresponding to the battery assembly position, the battery 15 is pushed to the battery assembly position 16 through the normal-close elastic assembly hole 18 so as to supply power to the circuit module 13. the normal-close elastic assembly hole 18 is kept closed due to elastic force in no working state, making the ball surface fully covered and ensuring a stronger elastic force. When to assemble the battery 15, the battery 15 is pushed to open the normal-close elastic assembly hole 18. the battery 15 is continued to be pushed until the battery 15 is positioned at the battery assembly position 16, the normal-close assembly hole 18 recovers to the initial state, closed state.

No matter the normal-close elastic assembly hole 18 is situated in close state or in battery being pushed 15 state, the battery assembly position 16 in the inner housing 12 is invisible; to make sure that the battery 15 can be pushed to the battery assembly position 16 quickly and correctly, the inner side surface of the inner housing of the battery assembly position 16 is disposed with a guide groove 19, the battery 15 is pushed along the guide groove 19; the guide groove 19 can also limit the battery 15 to prevent the battery 15 from shaking in the inner housing 12.

The battery assembly position 16 is disposed with a conductive sheet 14 corresponding to the electrode of the battery 15, the electrode of the battery 15 contacts with the conductive sheet 14 after the battery 15 is assembled to the battery assembly position 16, such to supply power to the circuit module 13. To make sure that the conductive sheet 14 contacted with the electrode of the battery 15 more nicely and efficiently and to prevent bad contact after long time's service, in this embodiment, the conductive sheet 14 is an elastic metal sheet connected to the circuit module 13. The conductive sheet 14 is an arc surface extending to the battery assembly position 16, the convex conductive sheet 14 is squeezed by the battery 15 and is deformed, such to contact tightly with the electrode of the battery 15. The convex side of the arc surface of the conductive sheet 14 is faced to the battery 15, therefore, the battery 15 is pushed easily and the conductive sheet 14 would not be damaged.

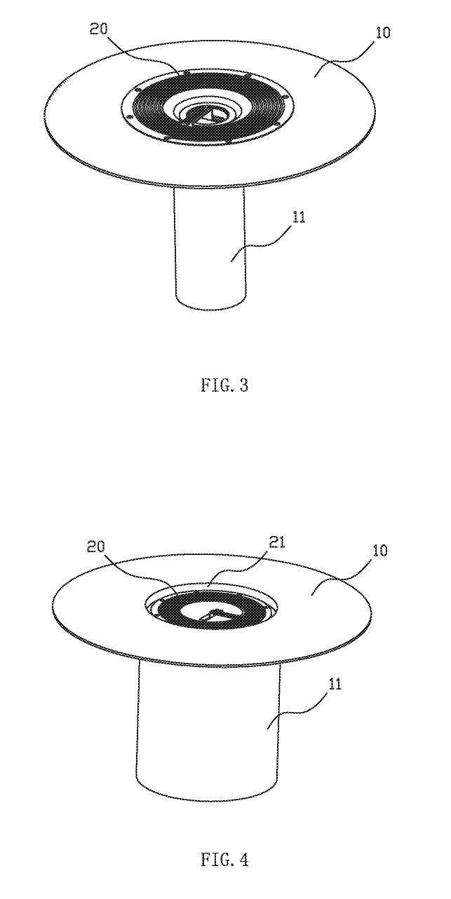

For a long time service, it should avoid changing the battery 15 frequently. In the present invention, the battery 15 is rechargeable, and the circuit module 13 comprises a wireless charging circuit, the battery 15 can be charged by wireless charging mode. The receiving coil 20 of the wireless charging circuit is disposed at the top surface of the connecting portion, as figured in FIG. 3, or is embedded in the sinking hole 21 of the connecting portion 10, as figured in FIG. 4, that is to say, the receiving coil 20 is contacted with the connecting portion 10; the wireless charging socket is only needed to direct to the elastic cover 17 to wireless charge the battery.

To achieve the device used to assembled a circuit module 13 and a battery 15 in a ball with normal integral elasticity, the present invention is further provided with a manufacturing method of the ball disposing with the device, the connecting portion and the ball interior can be vulcanized to an integration structure, in other cases, the connecting portion 10 can be adhered between the ball interior and the outer leather layer.

A manufacturing method of a ball disposed with the device, comprising the steps:
1) assembling the circuit module 13 in the inner housing 12, assembling the inner housing 12 in the assembly chamber 11;
2) vulcanizing the connecting portion 10 and the ball interior to an integration structure and wrapping the same (comprising splicing, stitching and other processes);
3) putting the elastic cover 17 at the top end opening of the assembly chamber 11, pushing the battery 15 through the normal-close elastic assembly hole 18 of the elastic cover 17 to the battery assembly position 16.

Another manufacturing method of a ball disposed with the device, comprising the steps:
1) assembling the circuit module 13 in the inner housing 12, assembling the inner housing 12 in the assembly chamber 11;
2) adhering the connecting portion 10 and the ball interior to an integration structure and wrapping the same (comprising splicing, stitching and other processes), the connecting portion 10 is disposed between the interior and the external wrapping layer;
3) putting the elastic cover 17 at the top end opening of the assembly chamber 11, pushing the battery 15 through the normal-close elastic assembly hole 18 of the elastic cover 17 to the battery assembly position 16.

### INDUSTRIAL APPLICABILITY

The device used to assemble a circuit module and a battery in a ball of the present invention is provided that the battery is not fixedly connected, the interior of the ball body is formed by high temperature vulcanization and wrapped by an external layer, then the batter is pushed through the normal-close elastic assembly hole of the elastic cover to the battery assembly position. The present invention avoids high temperature damaging the battery during the manufacturing.

Although the present invention has been described with reference to the preferred embodiments thereof for carrying out the patent for invention, it is apparent to those skilled in the art that a variety of modifications and changes may be made without departing from the scope of the patent for invention which is intended to be defined by the appended claims.

1. A device used to assemble a circuit module and battery in a ball, wherein comprising an inner housing, an assembly chamber and a connecting portion; the circuit module is fixedly assembled in the inner housing, the inner housing is disposed in the assembly housing, the top surface of the assembly housing extends outwardly to form the connecting portion, the opening of the top surface of the assembly chamber is disposed with an elastic cover; the inner housing is disposed with a battery assembly position, the elastic cover is disposed with a normal-close elastic assembly hole at the position according to the battery assembly position; the battery is pushed to the battery assembly position through the normal-close elastic assembly hole to provide power to the circuit module.

2. The device used to assemble a circuit module and a battery in a ball according to claim 1, wherein the battery assembly position is disposed with a conductive sheet corresponding to the electrode of the battery, the electrode of the battery contacts with the conductive sheet after the battery, which is used to supply power to the circuit module, is assembled to the battery assembly position.

3. The device used to assemble a circuit module and a battery in a ball according to claim 2, wherein the conductive sheet is an elastic metal sheet connected to the circuit module.

4. The device used to assembled a circuit module and a battery in a ball according to claim 3, wherein the conductive sheet is an arc surface extending towards the batter assembly position, the convex side of the arc surface is faced to the battery.

5. The device used to assemble a circuit module and a battery in a ball according to claim 1, wherein the elastic cover comprises two plug covers abutting against each other to close the opening of the assembly chamber, the position the two plug covers abutting against each other is disposed with the normal-close elastic assembly hole.

6. The device used to assemble a circuit module and a battery in a ball according to claim 1, wherein the internal side surface of the inner housing of the battery assembly position is disposed with a guide groove, the battery is pushed along the guide groove.

7. The device used to assemble a circuit module and a battery in a ball according to claim 1, wherein the inner housing is disposed with a limit groove, the circuit module is limited in the limit groove.

8. The device used to assemble a circuit module and a battery in a ball according to claim 1, wherein the battery is a rechargeable battery; the circuit module comprises a wireless charging circuit, a receiving coil of which is disposed at the top surface of the connecting portion or is embedded in a sinking hole of the connecting portion.

9. The device used to assemble a circuit module and a battery in a ball according to claim 1, wherein the connecting portion is a sheet shaped connecting surface horizontally extending outwardly from the top surface of the assembly chamber.

10. A manufacturing method of a ball disposed with the device according to claim 1, wherein comprising the steps:
1) assembling the circuit module in the inner housing, assembling the inner housing in the assembly chamber;
2) vulcanizing the connecting portion and the ball interior to an integration structure and wrapping the same;
3) putting the elastic cover at the top end opening of the assembly chamber, pushing the battery through the normal-close elastic assembly hole of the elastic cover to the battery assembly position.

11. A manufacturing method of a ball disposed with the device according to claim 1, wherein comprising the steps:
1) assembling the circuit module in the inner housing, assembling the inner housing in the assembly chamber;
2) adhering the connecting portion and the ball interior to an integration structure and wrapping the same, the connecting portion is disposed between the interior and the external wrapping layer;
3) putting the elastic cover at the top end opening of the assembly chamber, pushing the battery through the normal-close elastic assembly hole of the elastic cover to the battery assembly position.
